(19) United States
(12) Patent Application Publication
(10) Pub. No.: US 2014/0312877 A1
(43) Pub. Date: Oct. 23, 2014

(54) AC/DC-Sensitive Residual Current Protective Device (RCD) With Parameter Configuration

(71) Applicant: Bender GmbH & Co. KG, Gruenberg (DE)

(72) Inventor: Michael Kammer, Hungen (DE)

(73) Assignee: Bender GmbH & Co. KG, Gruenberg (DE)

(21) Appl. No.: 14/253,211

(22) Filed: Apr. 15, 2014

(30) Foreign Application Priority Data
Apr. 19, 2013 (DE) 10 2013 207 141.8

(51) Int. Cl. G01R 19/10

(52) U.S. Cl. CPC G01R 19/10
USPC 324/76.11

(57) ABSTRACT

A residual current protective device (RCD) and a method for AC/DC-sensitive differential current measurement with a voltage-dependent functional unit, which includes an AC/DC-sensitive differential current measuring device, has a current sensor and an AC/DC-sensitive current detection module. A microcontroller configures the voltage-dependent functional unit and evaluates the differential current detected by the AC/DC-sensitive differential current measuring device.

### CROSS-REFERENCE TO RELATED APPLICATIONS

This application claims priority to German Patent Application No. 10 2013 207 141.8 filed on Apr. 19, 2013, which is fully incorporated herein by reference.

### STATEMENT REGARDING FEDERALLYSPONSORED RESEARCH OR DEVELOPMENT

Not applicable.

### FIELD OF THE INVENTION

The invention relates to a residual current protective device (RCD) for AC/DC-sensitive differential current measurement and a method for AC/DC-sensitive differential current measurement.

### BACKGROUND OF THE INVENTION

Residual current protective devices (RCDs) are well-known as protective technology in electrical installations for protection in case of contact to bodies of electrical equipment and they are normatively required as protective measures in special areas of electrical installations.

The mode of action of a residual current protective device (RCD) of this kind is based on the fact that the vectorial sum of all currents on the current-carrying conductors of a supply line is zero in the fault-free operation of an electrical installation and no induction is generated in a magnet core of the residual current protective device (RCD). If because of an insulation fault a residual current occurs, which is discharged into a body or to ground outside of the supply line, a differential current is caused. A current is induced on the secondary side via the variable magnetic field of that differential current, said current triggering a power switch which separates the faulty supply line.

In a most simple and original variation, because of the induction principle, a residual current protective device (RCD) is only able to detect temporal changes in the magnetic flux and thus, in practice, to only detect pure alternating residual currents and alternating differential currents. However, loads connected to the electrical installation, such as electrical machines that have electronic semiconductor components like diodes or thyristors in rectifiers and frequency converters, can generate residual currents that do not have a purely sinusoidal path, but a pulsed temporal path. Hence, residual current protective devices (RCDs) were designed that are capable of detecting not only pure AC residual currents but also phase angle-controlled currents and pulsed DC residual currents. Such residual current protective devices (RCDs) sensitive to pulsed current are also called type A residual current protective devices (RCDs). There are also type B AC/DC-sensitive residual current protective devices (RCDs), which additionally recognize smooth DC residual currents.

Each of the trigger characteristics, which are predetermined by the different types of residual currents, requires a specific device variation, wherein the trigger value and the time delay are set as further functional parameters according to normative specifications. This leads to a wide variety of types accompanied by high production costs.

It proves to be another disadvantage of the residual current protective devices known from the state of the art that the manufacturers recommend a regular function test by means of a testing device by manually pushing a test button, but experience shows that this recommendation is rarely followed by the installation operators.

There are no residual current protective devices that offer the possibility of transferring data and which would thus be system-capable. Also, none of the residual current protective devices available on the market offer the possibility of displaying the determined residual current measured value for monitoring purposes, for example, or to notify the installation operator of a creeping increase of the residual current.

### SUMMARY OF THE INVENTION

Therefore, it is the object of the present invention to develop a residual current protective device (RCD) for AC/DC-sensitive differential current measurement whose production effort is accompanied by lowest possible costs and which proves reliable and versatile in operation.

Further, it is the object of the invention to provide a method for AC/DC-sensitive differential current measurement that can be implemented in the sense of the development objective for the residual current protective device.

The object is attained in connection with an AC/DC-sensitive differential current measurement with a voltage-independent differential current measuring device sensitive to pulsed current, which comprises a measuring current transformer, a power switch and a testing device for testing the differential current measuring device sensitive to pulsed current by a voltage-dependent functional unit with an AC/DC-sensitive differential current measuring device, composed of a current sensor and an AC/DC-sensitive current detection module, and with a microcontroller for configuring the voltage-dependent functional unit and for evaluating the differential current detected by the AC/DC-sensitive differential current measuring device.

Apart from a known voltage-independent differential current measuring device sensitive to pulsed current, which comprises a measuring current transformer, a power switch and a testing device, the residual current protective device comprises, according to the invention, a voltage-dependent functional unit with a microcontroller. Within the residual current protective device (RCD), said voltage-dependent functional unit can be understood as an RCD module for detecting AC/DC-sensitive residual currents. For this purpose, the functional unit comprises a differential current device, which is composed of a current sensor and of an AC/DC-sensitive current detection module, wherein the current sensor detects the conductor currents of the conductor to be monitored and transforms them into a secondary current, which is converted by the AC/DC-sensitive detection module into a voltage that can be evaluated by the microcontroller.

The microcontroller integrated in the voltage-dependent functional unit permits configuration and parameterization with respect to the trigger behavior of said voltage-dependent RCD module; i.e. the trigger characteristic can be parameterized according to the case of application by setting the function parameters, such as the trigger value or the time delay. Since in this manner a universally applicable RCD module for a residual current protective device (RCD) is created, the variety of types of necessary residual current protective devices (RCD) is decreased, accompanied by a reduction of costs in the production process and connected to a reduction of logistical effort.

The microcontroller takes over the task of evaluating the differential current detected by the AC/DC-sensitive differential current measuring device. Said evaluation can include calculating the effective value, wherein a result of said evaluation can be a detection of an exceedance of the trigger threshold and also a pre-warning in view of an imminent exceedance of the trigger threshold.

In a first design (variation 1), the testing device is embodied as a separate, manually triggerable testing device with a test button and a testing resistor for testing the voltage-independent differential current measuring device sensitive to pulsed current, whereas the voltage-dependent functional unit comprises a controlled testing device for testing the AC/DC-sensitive differential current measuring device.

Thus, the residual current protective device (RCD) comprises not only the manually triggerable testing device for the differential current measuring device sensitive to pulsed current, but also a further, controlled testing device for testing the AC/DC-sensitive differential current measuring device within the voltage-dependent functional unit. The manually triggerable testing device is composed of a test button and a testing resistor, whereas the controlled testing device can be activated automatically at certain points in time or in periodic intervals via the microcontroller, e.g. once a day, or it can also be activated manually via an operating unit. Beyond the test of the purely mechanical function, the controlled test can include a complete function test according to the parameterized trigger characteristic, the test signal consisting of the superposition of a direct and an alternating current and being led through the secondary winding (test winding) of the current sensor of the AC/DC-sensitive differential current measuring device. If the test fails, the power switch is triggered.

In an alternative design (variation 2), the residual current protective device (RCD) comprises a shared controlled testing device for testing the voltage-independent differential current measuring device sensitive to pulsed current and for testing the AC/DC-sensitive differential current measuring device.

Variation 2 thus differs from variation 1 by a testing device that tests the voltage-dependent differential current measuring device sensitive to pulsed current outside of the voltage-dependent functional unit and also the AC/DC-sensitive differential current device within the voltage-dependent functional unit. For this purpose, a test signal with a DC and an AC component is generated, which flows through the test windings of the current sensors (measuring current transformers) of the two differential current measuring devices. In an advantageous manner, this renders a separate testing device for testing the voltage-independent differential current measuring device unnecessary. Analogously to variation 1, a complete function test can either be induced by manual operation of the operating unit or be performed automatically at specific points in time.

The set object is attained in connection with AC/DC-sensitive differential current measurement with a power switch by another embodiment (variation 3), which is characterized by a voltage-dependent functional unit with an AC/DC-sensitive differential current measuring device, composed of a current sensor and an AC/DC-sensitive current detection module, and with a microcontroller for configuring the voltage-dependent functional unit and for evaluating the differential current detected by the AC/DC-sensitive differential current measuring device, the voltage-dependent functional unit comprising a controlled testing device for testing the AC/DC-sensitive differential current measuring device.

In this variation, the voltage-independent differential current measuring device is entirely omitted; in variations 1 and 2 it is present only because the current standardization in Germany requires this functionality. The embodiment according to variation 3 thus substantially corresponds to the voltage-dependent functional unit (RCD module) for AC/DC-sensitive differential current measurement with a power switch. In variations 1 and 2, the voltage-dependent functional unit comprises a microcontroller in addition to the AC/DC-sensitive differential current device and thus offers all advantages of the afore-mentioned variations. Thus, this supply voltage-dependent embodiment can be fully parameterized with regard to the trigger characteristic, in particular with regard to the trigger value and to the time delay.

All variations have the advantageous design features cited in the following.

The voltage-dependent functional unit has a digital programming interface for pre-setting configuration parameters during the production process of the residual current protective device (RCD). Via said programming interface, the trigger characteristic, the trigger value and the time delay of the voltage-dependent AC/DC-sensitive differential current measuring device can be pre-set during the production process. Thus, this design further adds to a decrease of the diversity of types and leads to further cost reduction at decreased logistical effort. In contrast, the supply voltage-independent differential current measuring device (present only in variations 1 and 2) cannot be parameterized.

In a further advantageous embodiment, the voltage-dependent functional unit comprises a digital communication interface for data transfer. The digital communication interface offers the possibility of transferring data during field operation, wherein the data can be functional parameters, i.e. allow configuration or parameterization of the trigger characteristic in the field (which, however, is not permitted according to current standards), and also operational or measuring data. For example, it is possible to exchange data with a control center for the purpose of transmitting measured values and to transmit operational data for maintenance purposes. Thus, the state of the installation can be centrally monitored. The data transfer via the digital communication interface can take place at programmable points in time, e.g. in the course of a function test, wherein said test can also include triggering the power switch. Via the digital communication interface, the residual current protective device (RCD) can be adapted to the requirements applying in different application situations and thus further add to a reduction in effort.

In an advantageous manner, the voltage-dependent functional unit comprises a display device for displaying the detected differential current. The display device locally shows the value of the differential current detected by the AC/DC-sensitive differential current measuring device and thus indicates the current insulation state of the electrical installation. With this information, it is recognizable by comparison with the trigger value set in the configuration process whether the monitored installation is at risk of an imminent shutdown due to the power switch being triggered because of a (threshold) exceedance.

Further, the voltage-dependent functional unit comprises a power source for providing a test current for the controlled testing device in variations 1 and 3 or for the shared controlled testing device in variation 2. The power source makes possible the function test of the AC/DC-sensitive differential current measuring device of the voltage-dependent functional unit in the course of the manual or automatic triggering according to the parameterized trigger characteristic.

Moreover, the voltage-dependent functional unit comprises an operating unit for inputting data and for manual process control. The operating unit allows, among other things, manually inducing a function test and parameterization during field operation. The latter approach, however, is not permitted according to current standards.

The voltage-dependent functional unit comprises a driver circuit and a switching step for transmitting a trigger signal to the power switch. Thus, an exceedance of the trigger value is transmitted in the form of a trigger signal via the driver circuit and the switching step to the power switch, which disconnects the load and thus the fault location from the supply voltage.

It is advantageous if the voltage-dependent functional unit comprises signaling devices for signaling warnings and operational states. Signaling devices of this kind can be embodied as optical andor acoustic devices and signal the trigger state or, prior thereto, issue a pre-warning when a threshold value below the trigger value is exceeded, for example.

Preferably, the voltage-dependent functional unit comprises a switching signal output for outputting at least one programmable switching signal. Via said switching signal output, it is possible, for example, to issue a pre-warning in the form of a switching signal that can be processed further when a threshold value below the trigger value is exceeded so as to be able to initiate the necessary repairs before the power switch is triggered.

In relation to a method, the object is attained in connection with AC/DC-sensitive differential current measurement, comprising a voltage-independent differential current measurement device sensitive to pulsed current, a power shutdown and a test of the differential current measuring device sensitive to pulsed current in that an AC/DC-sensitive differential current measurement takes place by means of a voltage-dependent functional unit with an AC/DC-sensitive differential current measuring device and the voltage-dependent functional unit is configured by means of a microcontroller and the differential current detected by the AC/DC-sensitive differential current measuring device is evaluated.

In correspondence to the residual current protective device (RCD) described herein, the method is based on the idea of performing an AC/DC-sensitive differential current measurement in a voltage-dependent functional unit in addition to the normatively required voltage-independent differential current measurement sensitive to pulsed current, and of being able to configure and parameterize by means of a microcontroller with regard to the trigger behavior and of being able to evaluate the differential current detected by the AC/DC-sensitive differential current measuring device.

Analogously to the above-described variation 1, the method corresponding to said variation is based on the fact that the test of the voltage-independent differential current measuring device sensitive to pulsed current takes place in a voltage-independent manner by means of a separate, manually triggerable testing device and that a test of the AC/DC-sensitive differential current measuring device is performed in a voltage-dependent manner by means of a controlled testing device.

Alternatively, the underlying method of the above-described variation 2 is based on the fact that a shared voltage-dependent test of the voltage-independent differential current measuring device sensitive to pulsed current and of the AC/DC-sensitive differential current measuring device takes place by way of a shared controlled testing device.

Further, the underlying object of the invention is attained in connection with AC/DC-sensitive differential current measurement including a power shutdown by a method corresponding to the above-illustrated variation 3, in which an AC/DC-sensitive differential current measurement is performed by way of a voltage-dependent functional unit with an AC/DC-sensitive differential current measuring device and the voltage-dependent functional unit is configured by means of a microcontroller and the differential current detected by the AC/DC-sensitive differential current measuring device is evaluated and wherein the AC/DC-sensitive differential current measuring device is tested in a voltage-dependent manner by means of a controlled testing device.

Since all method variations form the basis for the corresponding implementation of the methods into the respective variation of the residual current protective device (RCD), the advantages explained above for the residual current protective device (RCD) apply equally to the method features.

The configuration of the voltage-dependent functional unit comprises in particular a setting of the functional parameters response value, time delay and a parameterization of the trigger characteristic, which makes it possible to use a residual current protective device (RCD) based on the application of the method for monitoring different types of residual currents.

The evaluation of the differential current detected by the AC/DC-sensitive differential current measuring device by means of the microcontroller involves in a convenient manner one or more of the following steps: calculating an effective value, comparing a threshold value including generating the trigger signal, signaling warnings and operational states, generating and outputting programmable switching signals.

Calculating the effective value advantageously leads to a measuring result that is independent of the waveform of the differential current, i.e. independent of the type of the residual current.

Signaling warnings and operational states allows the trigger state and the pre-warning to be optically displayed when a threshold value below the trigger threshold is exceeded. A pre-warning of this kind makes it possible for the installation operator to carry out repairs before a further deterioration of the insulation state leads to an automatic shutdown of the installation by the residual current protective device (RCD).

### BRIEF DESCRIPTION OF THE DRAWINGS

Further advantageous embodiment features arise from the following description and from the drawings, which illustrate preferred embodiments of the invention with the aid of examples. In the figures:

FIG. 1: shows a residual current protective device of the invention according to variation 1;

FIG. 2: shows a residual current protective device of the invention according to variation 2; and

FIG. 3: shows a residual current protective device of the invention according to variation 3.

### DETAILED DESCRIPTION OF THE EXAMPLE EMBODIMENTS

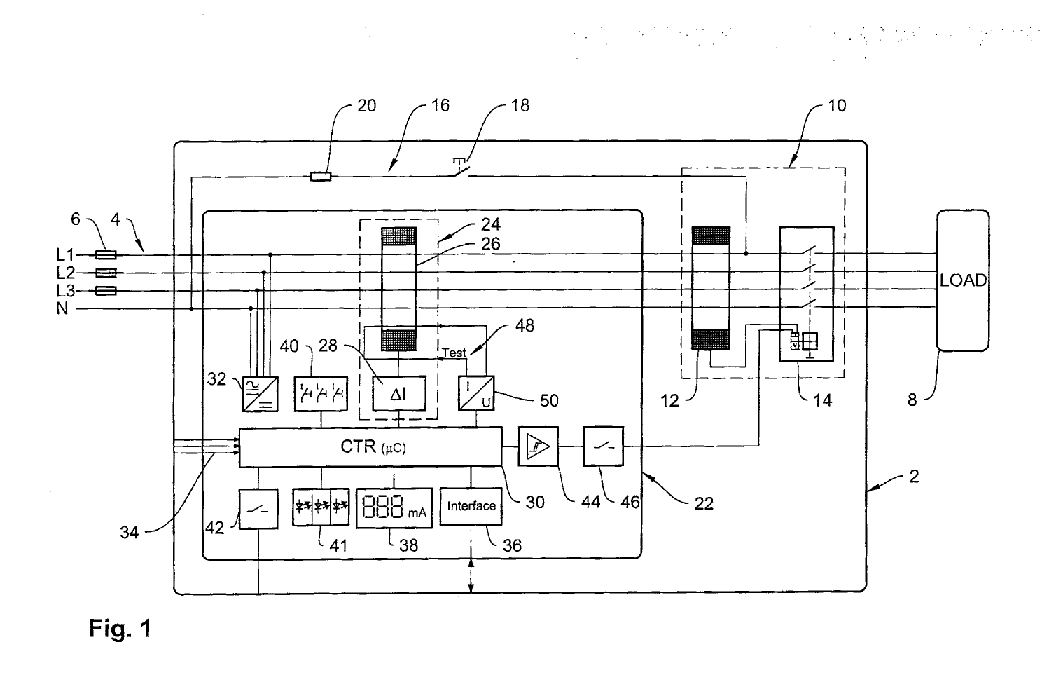

FIG. 1 shows a residual current protective device (RCD) 2 of the invention according to variation 1, which is provided as a protective measure against electric shock in a power supply system 4. The power supply system 4 is illustrated as a three-phase network by the active conductors L1, L2, L3 and N, which are secured on the injection side by overcurrent protection devices (fuses) 6 and are connected to a load 8 on the load side.

The residual current protective device (RCD) 2 comprises a (supply) voltage-independent differential current measuring device 10 sensitive to pulsed current, which is composed of a measuring current transformer 12, a power switch 14 and a testing device 16 with a test button 18 and a testing resistor 20. To detect the differential current, the measuring current transformer 12 encloses the active conductors L1, L2, L3 and N of the power supply system 4. In principle, the residual current protective device (RCD) is capable of monitoring any kind of power supply system, including single-phase networks or three-phase networks without neutral conductors, for example.

As substantial elements, the residual current protective device (RCD) 2 according to the invention comprises a voltage-dependent functional unit 22 with an AC/DC-sensitive differential current measuring device 24 and with a microcontroller 30. The AC/DC-sensitive differential current measuring device 24 is composed of a current sensor 26 (measuring current transformer) and an AC/DC-sensitive current detection module 28.

To ensure a reliable function of the voltage-dependent functional unit 22, it is connected at all poles to the power supply system 4 via a supply unit 32 so that the AC/DC-sensitive protective function is maintained in case a phase or the neutral conductor fails. The microcontroller 30 serves to configure the voltage-dependent functional unit 22 and to AC/DC-sensitively evaluate the differential current detected by the current sensor 26 on the active conductors L1, L2, L3 and N.

Via a programming interface 34 of the microcontroller 30, the configuration and the parameterization according to the measuring task can take place by setting the functional parameters, such as trigger value, time delay and trigger characteristic, during the production process of the residual current protective device (RCD) 2. In the same way, parameterization can be performed in field operation via a communication interface 36. The communication interface 36 further serves to transfer measured values or to transmit operational data for maintenance purposes.

For displaying the detected differential current, an optical display device 38 is provided.

An operating unit 40 permits inputting data and allows manually controlling the measuring and testing processes. Thus, a manual function test can be initiated or the parameterization in field operation can be performed via the operating unit 40.

Further, the voltage-dependent functional unit 22 comprises signaling devices 41 for signaling warnings and operational states. For example, the signaling devices 41 serve to display the trigger state and to signal the pre-warning when a threshold value below the trigger threshold is exceeded.

For outputting programmable switching signals, the voltage-dependent functional unit 22 comprises a switching signal output 42. Said switching signal output 42 can be used for leading a switching signal, which was generated upon a threshold value exceedance, to the outside so as to automatically initiate further measures. For example, a threshold value below the trigger threshold of the residual current protective device (RCD) 2 can be parameterized such that the operator of the installation is informed by a warning signal that a shutdown of power switch 14 due to an excess differential current is imminent. Outputting multiple switching signals is possible as well. In case the trigger value is exceeded, the trigger signal is transmitted by way of a driver circuit 44 and a switching step 46 to the power switch 14 in order to separate the load 8 from the power supply system 4.

For testing the AC/DC-sensitive differential current measuring device 24, a controlled testing device 48 with a power source 50 is provided, which supplies a test current as a test signal to the test winding of the current sensor 26. Thus, a function test according to the parameterized trigger characteristic can be performed, the test current consisting of the superposition of a DC and an AC component.

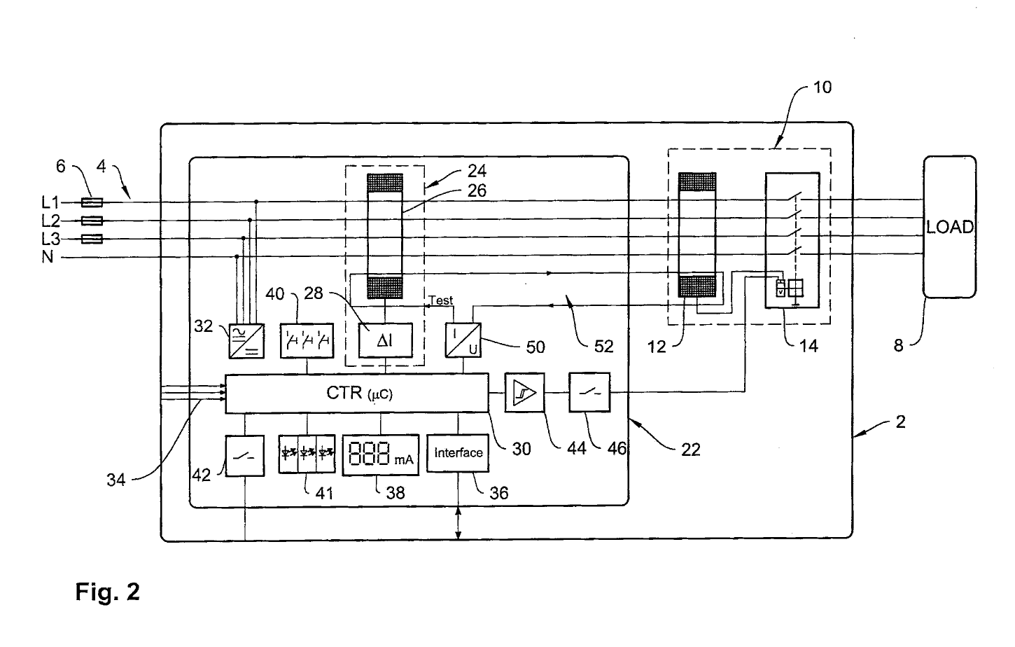

In FIG. 2, a residual current protective device (RCD) 2 of the invention according to variation 2 is illustrated. Variation 2 differs from variation 1 shown in FIG. 1 only in that it comprises a shared controlled testing device 52 for the function test of the voltage-independent differential current measuring device 10 sensitive to pulsed current and for testing the AC/DC-sensitive differential current measuring device 24. The shared controlled testing device 52 thus covers both the passive monitoring part with the voltage-independent differential current measuring device 10 and the active monitoring with the voltage-dependent differential current measuring device 24. The test signal generated by the power source 50 consists of a DC and an AC component and runs through the test winding of the measuring current transformer 12 of the voltage-independent differential current measuring device 10 sensitive to pulsed current and through the test winding of the current sensor 26 of the AC/DC-sensitive differential current measuring device 24. The manual testing device 16 with the test button 18 and the testing resistor 20 used in variation 1 can thus be omitted. Like in variation 1, the function test can be performed by manual operation at the operating unit 40 or take place automatically, controlled via the microcontroller 30, at defined points in time, e.g. in periodic intervals.

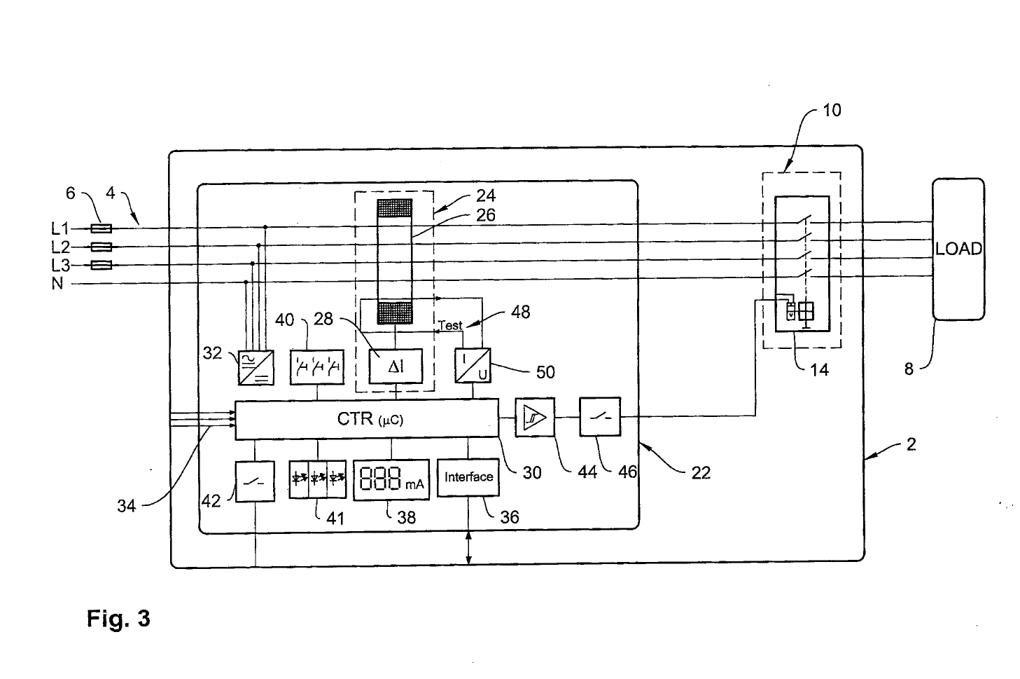

FIG. 3 shows a residual current protective device of the invention according to variation 3, which, with the voltage-dependent functional unit 22, now has an active AC/DC-sensitive monitoring part. A voltage-independent differential current measuring device 10 has been omitted; it is only present in variations 1 and 2 because current standards require that functionality. Variation 3 thus corresponds to variation 1 without the voltage-independent differential current measuring device 10 and represents a supply voltage-dependent version of a residual current protective circuit (RCD) whose functional parameters can be fully parameterized, in particular with regard to the trigger characteristic, the trigger value and the time delay.

1. A residual current protective device (RCD) for AC/DC-sensitive differential current measurement with a voltage-independent differential current measuring device sensitive to pulsed current, the voltage-independent differential current measuring device including a measuring current transformer, a power switch, and a testing device for testing the differential current measuring device sensitive to pulsed current, said current protective device comprising:
a voltage-dependent functional unit with an AC/DC-sensitive differential current measuring device detecting a differential current, said AC/DC-sensitive differential current measuring device including a current sensor and an AC/DC-sensitive current detection module; and
a microcontroller for configuring the voltage-dependent functional unit and for evaluating the differential current detected by the AC/DC-sensitive differential current measuring device.

2. The residual current protective device (RCD) according to claim 1, in which the testing device is a separate, manually triggerable testing device with a test button and a testing resistor testing the voltage-independent differential current measuring device sensitive to pulsed current, and that the voltage-dependent functional unit includes a controlled testing device testing the AC/DC-sensitive differential current measuring device.

3. The residual current protective device (RCD) according to claim 1, including a shared controlled testing device for testing the voltage-independent differential current measuring device sensitive to pulsed current and testing the AC/DC-sensitive differential current measuring device.

4. A residual current protective device (RCD) for AC/DC-sensitive differential current measurement with a power switch, said current protective device comprising:
a voltage-dependent functional unit with an AC/DC-sensitive differential current measuring device including a current sensor and an AC/DC-sensitive current detection module, the voltage-dependent functional unit including a controlled testing device for testing the AC/DC-sensitive differential current measuring device; and
a microcontroller configuring the voltage-dependent functional unit and evaluating a differential current detected by the AC/DC-sensitive differential current measuring device.

5. The residual current protective device (RCD) according to claim 1, in which the voltage-dependent functional unit includes a digital programming interface presetting configuration parameters during a production process of the residual current protective device (RCD).

6. The residual current protective device (RCD) according to claim 1, in which the voltage-dependent functional unit includes a digital communication interface for data transfer.

7. The residual current protective device (RCD) according to claim 1, in which the voltage-dependent functional unit includes a display device for displaying the detected differential current.

8. The residual current protective device (RCD) according to claim 1, in which the voltage-dependent functional unit includes a power source providing a testing current for the controlled testing device or for the shared controlled testing device.

9. The residual current protective device (RCD) according to claim 1, in which the voltage-dependent functional unit includes an operating unit for inputting data and for manual process control.

10. The residual current protective device (RCD) according to claim 1, in which the voltage-dependent functional unit includes a driver circuit and a switching step for transmitting a trigger signal to the power switch.

11. The residual current protective device (RCD) according to claim 1, in which the voltage-dependent functional unit includes signaling devices signaling at least one of a warnings and an operational states.

12. The residual current protective device (RCD) according to claim 1, in which the voltage-dependent functional unit includes a switching signal output for outputting at least one programmable switching signal.

13. A method for AC/DC-sensitive differential current measurement, including a voltage-independent differential current measurement device sensitive to pulsed current, a power shutdown and a test of the differential current measuring device sensitive to pulsed current, said method comprising:
detecting an AC/DC-sensitive differential current using a voltage-dependent functional unit with an AC/DC-sensitive differential current measuring device, the voltage-dependent functional unit being configured by a microcontroller; and
evaluating the differential current detected by the AC/DC-sensitive differential current measuring device.

14. The method according to claim 13, including
testing the voltage-independent differential current measuring device sensitive to pulsed current in a voltage-independent manner by separate, manually triggerable testing device; and
testing the AC/DC-sensitive differential current measuring device in a voltage-dependent manner by a controlled testing device.

15. The method according to claim 13, including a shared voltage-dependent test of the voltage-independent differential current measuring device sensitive to pulsed current and of the AC/DC-sensitive differential current measuring device takes place by way of a shared controlled testing device.

16. A method for AC/DC-sensitive differential current measurement including a power shutdown, said method comprising:
detecting an AC/DC-sensitive differential current using a voltage-dependent functional unit with an AC/DC-sensitive differential current measuring device and the voltage-dependent functional unit is configured by means of a microcontroller;
evaluating the differential current detected by the AC/DC-sensitive differential current measuring device; and
testing the AC/DC-sensitive differential current measuring device in a voltage-dependent manner by a controlled testing device.

17. The method according to claim 13, in which configuring the voltage-dependent functional unit includes setting functional parameters of response value, time delay and a parameterization of a triggering characteristic.

18. The method according to claim 13, including inputting configuration parameters via a digital programming interface to preset configuration parameters during a production process of the residual current protective device (RCD)₍₂₎.

19. The method according to claim 13, including transferring data via a digital communication interface.

20. The method according to claim 13, including displaying the detected differential current via a display device (38).

21. The method according to claim 13, including providing a test current for the controlled testing device or for the shared controlled testing device by a power source.

22. The method according to claim 13, in which a manual data input and a manual process control take place via an operating unit.

23. The method according to claim 13, including transmitting a trigger signal to the power switch using a driver circuit and a switching step.

24. The method according to claim 13, in which evaluating the differential current detected by the AC/DC-sensitive differential current measuring device using the microcontroller includes one or more of the following steps:
calculating an effective value,
comparing a threshold value including generating the trigger signal,
signaling warnings and operational states, and
generating and outputting programmable switching signals.
